(19) United States
(12) Patent Application Publication
(10) Pub. No.: US 2009/0157350 A1
(43) Pub. Date: Jun. 18, 2009

(54) OBTAINING A PROTON DENSITY DISTRIBUTION FROM NUCLEAR MAGNETIC RESONANCE DATA

(75) Inventors: Rafael Salazar-Tio, San Ramon, CA (US); Boqin Sun, Concord, CA (US)

Correspondence Address: CHEVRON CORPORATION, P.O. BOX 6006, SAN RAMON, CA, 94583-0806, US

(73) Assignee: Chevron U.S.A. Inc.

(21) Appl. No.: 11/954,556

(22) Filed: Dec. 12, 2007

(51) Int. Cl. G06F 17/18; G01R 33/20

(52) U.S. Cl. 702/179; 324/307

(57) ABSTRACT

A computer-implemented method enables a proton density distribution to be obtained. In one embodiment, the method comprises acquiring nuclear magnetic resonance data from porous media; inverting the nuclear magnetic resonance data via a global optimization algorithm to determine a proton density distribution within the porous media; and outputting the determined proton density distribution.

### FIELD OF THE INVENTION

The invention relates to obtaining a proton density distribution from nuclear magnetic resonance data.

### BACKGROUND OF THE INVENTION

Nuclear magnetic resonance systems that manipulate spins of molecules present in a porous media are known. These systems generally perform at least the following functionality to determine information related to the porous median and/or fluids contained therein: polarizing spins through static magnetic fields, manipulating the spins through radio frequency (“RF”) pulses, and receiving the response of spins through RF signals emanating from the porous media. The RF signals are then processed to determine information related to the composition of the porous media and/or one or more fluids contained, or “bound,” within the porous media.

### SUMMARY

One aspect of the invention relates to a computer-implemented method of obtaining a proton density distribution. In one embodiment, the method comprises acquiring nuclear magnetic resonance data from porous media; inverting the nuclear magnetic resonance data via a global optimization algorithm to determine a proton density distribution within the porous media; and outputting the determined proton density distribution.

Another aspect of the invention relates to a computer-implemented method of obtaining a proton density distribution. In one embodiment, the method comprises acquiring nuclear magnetic resonance data from porous media; determining a proton density distribution of the porous media from the nuclear magnetic resonance data, wherein the proton density distribution comprises one or more spectra comprised of a plurality of predetermined zones, one or more of the predetermined zones having a peak of the distribution therein, and wherein determining the proton density distribution comprises parameterizing the proton density distribution according to a non-linear basis function by fitting a single basis component to the distribution in each of the predetermined zones that has a peak of the distribution therein; and outputting the determined proton density distribution.

Another aspect of the invention relates to a method of obtaining information related to a proton density distribution. In one embodiment, the method comprises acquiring nuclear magnetic resonance data from media; defining a function that implements the acquired nuclear magnetic resonance data and depends on m parameters of the proton density distribution such that the function is minimized as a solution for the m parameters of the proton density distribution is approached; implementing a global optimization algorithm to determine the solution for the m parameters of the proton density distribution; and outputting the solution for the m parameters of the proton density distribution.

These and other objects, features, and characteristics of the present invention, as well as the methods of operation and functions of the related elements of structure and the combination of parts and economies of manufacture, will become more apparent upon consideration of the following description and the appended claims with reference to the accompanying drawings, all of which form a part of this specification, wherein like reference numerals designate corresponding parts in the various figures. It is to be expressly understood, however, that the drawings are for the purpose of illustration and description only and are not intended as a definition of the limits of the invention. As used in the specification and in the claims, the singular form of “a”, “an”, and “the” include plural referents unless the context clearly dictates otherwise.

### BRIEF DESCRIPTION OF THE DRAWINGS

FIG. 1 illustrates a method of implementing nuclear magnetic resonance to determine information about porous media, according to one embodiment of the invention.

FIG. 2 provides an exemplary plot of nuclear magnetic resonance data, in accordance with one embodiment of the invention.

FIG. 3 provides an exemplary illustration of a proton density distribution, according to one embodiment of the invention.

FIG. 4 illustrates a three dimensional surface with both local minima and an absolute minimum.

FIG. 5 illustrates the surface shown in FIG. 4 with further local minima associated with noise.

FIG. 6 illustrates one embodiment of a method of implementing a global optimization algorithm in accordance with one embodiment of the invention.

FIG. 7 illustrates a method of inverting nuclear magnetic resonance data via a global optimization algorithm to determine a proton density, according to one embodiment of the invention.

FIG. 8 illustrates a proton density distribution.

### DETAILED DESCRIPTION

Nuclear magnetic resonance (“NMR”) technology has been widely used to measure properties of fluid containing porous media (e.g., petrophysical properties of geological formations, various properties of living tissue, structural properties of chemical compounds, etc.). Examples of some petrophysical properties include pore size, surface-to-volume ratio, formation permeability, and capillary pressure. In determining these properties, parameters such as longitudinal relaxation time (“T₁”), transverse relaxation time (“T₂”), and a diffusion coefficient (“D”) are often of interest. Relaxation time is the time associated with nuclear spins to return to their equilibrium positions after excitation. The longitudinal relaxation time T₁ relates to the alignment of spins with an external static magnetic field. Transverse relaxation time T₂ is a time constant that identifies the loss of phase coherence that occurs among spins oriented to an angle to the main magnetic field. This loss is caused, in part, by the interactions between spins. The diffusion coefficient D is the diffusion coefficient of the pore fluid.

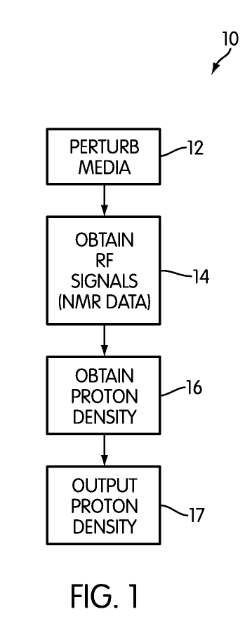

FIG. 1 illustrates a method 10 of implementing NMR to determine information about porous media and/or fluid(s) contained therein. It should be appreciated that although certain aspects of method 10 are described herein within the context of implementing NMR to determine information related to geological media, this is not intended to limit the scope of the disclosure. The scope of this disclosure includes the implementation of NMR for examining media outside of geological media (e.g., living tissue, etc.). In one embodiment, method 10 is a computer-implemented method executed on one or more processors.

At an operation 12, the porous media and the fluids contained therein are perturbed with a chain of RF pulses called a “pulse sequence.” In one embodiment, the perturbation is accomplished in accordance with a Carr-Purcell-Meiboom-Gill (CPMG) pulse sequence. In some embodiments, other sequences are implemented to perturb the porous media and the fluids contained therein.

A regular CPMG pulse sequence includes a 90 degree pulse followed by a series of 180 degree pulses, and comports with the following expression:

$${{( \frac{π}{2} )}_{\pm x} [ - {τ}_{k} - {π}_{y} - {τ}_{k} - acq - ]}_{nk} ; \qquad ( 1 )$$

where π/2 is a 90 degree pulse applied along the plus and minus x-axis with respect to a reference in the rotating frame; τₖ represents half of the echo spacing TEₖ of the k-th echo train; π represents a 180 degree pulse applied along y axis in the rotating frame; acq represents an acquisition of an echo; nₖ is the number of echoes in the k-th echo train.

Accompanying the regular CPMG pulse sequence is an external magnetic field gradient Gₖ and an optional pulse gradient applied between 180 degree RF pulses. The width of the pulse field gradient is represented by δₖ and the separation between successive gradient pulses is represented by Δₖ. Meanwhile the system of nuclear spins is also subjected to the internal field gradient caused by the external magnetic field and susceptibility contrast between grains and pore fluids. In the following a symbol g represents the total magnetic field gradient to which the system of nuclear spins is subjected.

At an operation 14, RF signals from within the porous media are obtained. These signals are generally referred to as NMR data, “echo data,” or NMR log data. As is discussed further below, these signals are indicative of one or more echo trains produced in the porous media in response to the pulse sequence of operation 12. Information about the echo trains conveyed by the signals obtained at operation 14 enable measurement of one or more properties of the porous media and/or fluid(s) contained therein (e.g., the properties enumerated above). In certain embodiments, operations 12 and 14 are performed using known NMR logging tools and/or NMR spectrometers.

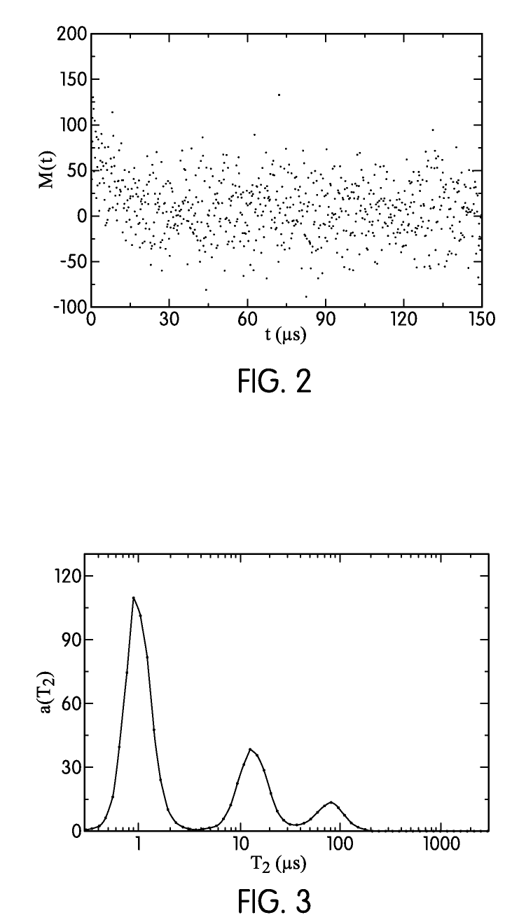

The NMR data M(tᵢ) obtained at operation 14 that corresponds to one echo train of a pulse sequence has the following form relating the data M(tᵢ) to the parameters T₁ relaxation time, T₂ relaxation time, and diffusion coefficient D:

$$M ( {t}_{i} ) = {\sum }_{j = 1}^{{m}_{1}} {\sum }_{k = 1}^{{m}_{2}} {\sum }_{l = 1}^{{m}_{3}} a ( {T}_{1 k} , {T}_{2 j} , {D}_{l} ) {e}^{- {t}_{i} / {T}_{2 j}} ( 1 - {e}^{- WT / {T}_{1 k}} ) {e}^{- {γ}^{2} {g}^{2} {t}_{E}^{2} {D}_{l} {t}_{i} / 12} + {ɛ}_{i} ; \qquad ( 2 )$$

where t_{E} represents the time between echos, γ represents the gyromagnetic ratio, WT represents the wait time between echo trains, a(PARAMETERS) represents the amplitude of a given parameter set (e.g., PARAMETERS=T₁, T₂, and/or D), and εᵢ represents the noise present in the NMR data M(tᵢ). FIG. 2 provides an exemplary plot of actual data obtained at operation 14, M(tᵢ), as a function of time.

Returning to FIG. 1, in some instances, two or more of the parameters T₁, T₂, and/or D may be eliminated from equation (2). For example, when the magnetic field is considered uniform, the gradient, g, of the magnetic field equals 0 and the third exponential term e^{-γ}^{²}^{g}^{²}^{t}^{_{E}}^{²}^{D}^{₁}^{t}^{ᵢ}^{/12}, called the diffusion kernel, becomes approximate to 1 so that the equation becomes independent from D. Similarly, when the wait time WT is large enough, the second exponential term (1−e^{-WT/T}^{₁ₖ}), called the polarization factor, becomes approximate to 1 and the equation becomes independent from T₁. Or, the polarization factor can be made independent of T₁ by using an effective ratio r=T₁/T₂. In this case the k-sum disappears too. In instances in which equation (2) becomes independent from T₁ and D, the relationship between M(tᵢ) and T₂ can be represented as:

$$M ( {t}_{i} ) = {\sum }_{j = 1}^{m} a ( {T}_{2 j} ) {e}^{- {t}_{i} / {T}_{j}} ( 1 - {e}^{- WT / {rT}_{j}} ) + {ɛ}_{i} ; \qquad ( 3 )$$

where M(tᵢ) represents the ith echo amplitude measured(i=1, . . . , n), tᵢ represents a set of n decay times equally spaced, and εᵢ, is the noise of the ith echo. T₂ⱼ represents a set of m pre-selected T₂ relaxation times equally spaced on a logarithmic scale, and a(T₂ⱼ) is the T₂ amplitude distribution associated with the relaxation time T₂ⱼ to be solved by this model.

Hereafter, this disclosure primarily describes the processing of NMR data obtained at operation 14 in instances in which the echo train(s) represented in the NMR data are computationally independent from T₁ and D (i.e., M(tᵢ) depends primarily on T₂). These instances are generally referred to as single-dimension NMR solutions. However, this is not intended to be limiting. It should be appreciated that the techniques and methods described herein with respect to single-dimension NMR solutions could easily be extended to NMR solutions of more than one dimension (e.g., instances in which M(tᵢ) depends on T₁ and/or D, as well as T₂).

At an operation 16, a proton density distribution is obtained from the NMR data obtained at operation 14. The proton density distribution obtained is a function of the parameters (e.g., T₁, T₂, and/or D) upon which M(tᵢ) depends (e.g., T₂ in a single-dimension NMR solution). For example, FIG. 3 provides an exemplary illustration of a proton density distribution a(T₂ⱼ) obtained from the NMR data represented in FIG. 2.

Referring back to FIG. 1, in one embodiment, obtaining the proton density distribution from the NMR data comprises performing an inversion to determine the distribution from the relationship represented in equation (3). For example, formal mathematical solution for the distribution a(T₂ⱼ) represented by equation (3), without the noise term εᵢ, is given by an inverse Laplace transform. However the noise term εᵢ makes this technique unpracticable because the inversion is non-unique. Another approach is to restate equation (3) as a least square minimization:

$${χ}^{2} [ \{ a ( {T}_{j} ) \} ] = {\sum }_{i = 1}^{n} {[ M ( {t}_{i} ) - {\sum }_{j = 1}^{m} a ( {T}_{2 j} ) {e}^{- {t}_{i} / Tj} ( 1 - {e}^{- WT / {rT}_{j}} ) ]}^{2} ; \qquad ( 4 )$$

which is solved for the optimal discrete distribution a(T₂ⱼ) that makes χ² minimum.

At an operation 17, the proton density distribution obtained at operation 16 is output. This may include electronic storage of the distribution, electronic display of the distribution (e.g., graphical display), electronic transmission of the distribution, or any other method for outputting information derived by a computer-implemented method.

Generally, the approach taken to determine a solution to this least square minimization at operation 16 includes implementing a Singular Value Decomposition (“SVD”). To present a brief description of this conventional technique, we rewrite equations (3) and (4) as:

$$\begin{matrix}{b}_{i} = {\sum }_{j = 1}^{m} {K}_{ij} {a}_{j} + {ɛ}_{i} ; and & ( 5 ) \\ {χ}^{2} [ \{ {a}_{j} \} ] = {\sum }_{i = 1}^{n} {[ {b}_{i} - {\sum }_{j = 1}^{m} {K}_{ij} {a}_{j} ]}^{2} ; & ( 6 )\end{matrix}$$

where bᵢ=M(tᵢ), aⱼ=a(T₂ⱼ), and Kᵢⱼ=e^{-t}^{ᵢ}^{/T}^{ⱼ} (1−e^{-WT/rT}^{ⱼ}).

In matrix form, equations (5) and (6) become:

b=K·a+ε; and (7)

χ²(a)=|K·a−b|²; (8)

where the matrix elements correspond to the components of equations (5) and (6). In order to solve equation (8), the condition ∇χ²=0 is applied, which has to be satisfied in order χ² to be minimum. This yields:

K^{T}·(K·a−b)=0; which simplifies to: (9)

(K^{T}·K)·a=K^{T}·b; which further simplifies to: (10)

\tilde{K}·a=\tilde{b}; (11)

where the superscript “T” which stands for Transpose. Equation (11) is a lineal system of equations, which could be solved using an algebraic method, such as Gauss-Jordan elimination. However, because of the noise term εᵢ the matrix K is singular or near singular. This is primarily because the matrix K is overdetermined (i.e., K is an n×m matrix, where n>m), which creates ambiguous possible solutions a within the uncertainty given by the noise, producing an effectively underdetermined system.

The SVD form of the matrix K is:

K=U·[diag(wᵢ)]·V^{T}; (12)

where U is a [m×n] column orthogonal matrix, V is an [n×n] orthogonal matrix, and W is a [n×n] diagonal matrix with positive or close to zero elements (the singular values). A cut-off condition related with the global noise level of the data is used to make zero all the diagonal values which satisfy wᵢ≦wₘₐₓ×δ_{cutoff}, with typical values δ_{cutoff}=10⁻⁵. Using the SVD form of K in equation (11), the solution for a can be expressed as:

$$a = {\sum }_{i = 1}^{m} ( \frac{{U}_{( i )} \cdot b}{{w}_{i}} ) {v}_{( i )} ; \qquad ( 13 )$$

where the vectors U₍ᵢ₎, i=1, . . . , m denote the columns of U (each one a vector of length n), and the vectors V⁽ⁱ⁾, i=1, . . . , m denote the columns of V (each one a vector of length m). Equation (13) specifies that the fitted parameters a are lineal combinations of the columns of V, with the coefficients obtained by forming dot products of the columns of U with the weighted data vector b.

Even though the cut-off condition is meant to smooth out all noise effects, in practice it is not enough to produce smooth amplitude distributions, where some spikes could appear. An additional term is added to equation (13) called a “regularization term,” which is intended to minimize the norm, slope, or curvature of the distribution with some factor to be determined by a searching method which matches the data noise level in the data obtained from operation 14.

In one embodiment, as an alternative to SVD and/or other conventional techniques for performing an inversion on obtained NMR data to obtain a proton density distribution, a global optimization algorithm is implemented. More specifically, the function χ²(a) is viewed as an m dimensional surface, and the global optimization algorithm is implemented to determine the absolute minimum of the surface. The m-space vector coordinates of the determined absolute minimum of the surface correspond to the proton density distribution with respect to the parameters (e.g., T₂) on which M(tᵢ) depends.

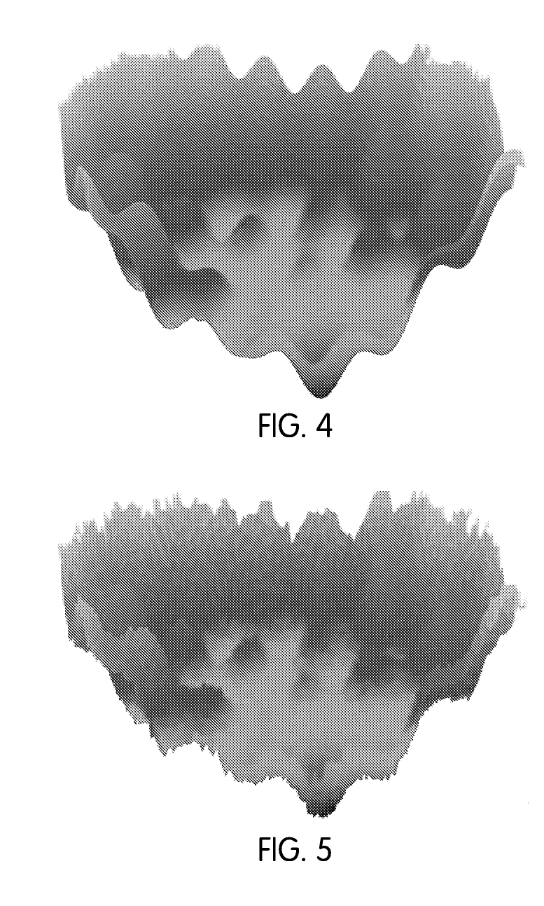

Determining the absolute minimum of the m dimensional surface of χ²(a) is non-trivial in part because the surface likely includes a plurality of local minima. For this reason, conventional optimization algorithms that use local gradient information to detect a surface minimum, such as Levenberg-Marquardt or conjugate gradient, are not practical (as they will usually produce a local minimum instead of the absolute minimum). For example, FIG. 4 illustrates a 3 dimensional surface with both local minima and an absolute minimum. It should be appreciated from FIG. 4, that an optimization algorithm that does not provide for global optimization may become “stuck” in one of the local minima.

In one embodiment, in order to reduce the chances of returning a local minimum, the optimization algorithm implemented at operation 16 is a global optimization algorithm. As used herein, the term “global optimization algorithm” means any algorithm or set of algorithms that can be executed to optimize a function or set of functions to some predetermined criteria. Generally, a global optimization algorithm will require a series of iterations that enable the algorithm to converge on the optimization. For example, the global optimization algorithm may include one or more of a stochastic optimization (e.g., simulated annealing, parallel tempering, etc.), a Heuristic or metaheuristic optimization (e.g., genetic algorithm, evolutionary strategies, etc.), and/or other optimizations.

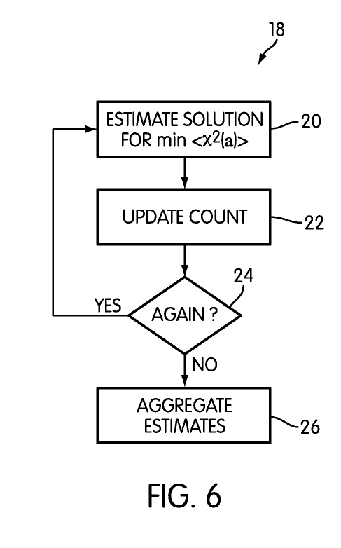

The inversion achieved by implementing a global optimization algorithm to obtain proton density distribution from NMR data is merely an estimation of the absolute minimum of the χ²(a) function. Further, the noise present in the data obtained at operation 14 may further complicate determining the minimum χ²(a). For example, FIG. 5 illustrates the surface shown in FIG. 4 with further local minima associated with noise. As should be appreciated from FIG. 5, as what would be the minimum of χ²(a) in the absence of noise is approached (e.g., the minimum of χ²(a) in FIG. 4) the local minima caused by noise that surround this minimum create a multiplicity of equivalent (or substantially equivalent) solutions for the minimum of χ²(a). As such a single solution achieved via a global optimization algorithm may not provide the absolute minimum of the χ²(a) function because the global optimization algorithm may return one of the minima associated with noise instead of the actual minimum. FIG. 6 illustrates a method 18 of implementing a global optimization algorithm to account (at least to some extend) for a multiplicity of equivalent solutions caused by noise. In one embodiment, method 18 ensures that the result obtained will provide sufficient accuracy. In some instances, method 18 may be implemented at operation 16 of method 10 (shown in FIG. 1 and described above). However, this is not intended to be limiting.

Method 18 includes an operation 20, at which a solution for the absolute minimum of the χ²(a) function is obtained using a global optimization algorithm. At an operation 22, a count of the number of times a solution for the χ²(a) function has been obtained is updated (e.g., addition of 1 to reflect the solution of operation 20). At an operation 24, a determination is made as to whether additional estimates of the solution for the absolute minimum of χ²(a) are necessary. In one embodiment, this determination includes comparing the count updated at operation 22 with a predetermined threshold. If additional estimates are required, then method 18 goes back to operation 20. If no additional estimates are necessary, then method 18 proceeds to operation 26. At operation 26 the estimates of the solution determined at operation 20 are aggregated to provide a final estimation of the solution for the absolute minimum of the χ²(a) function. For example, the aggregation may include averaging the estimates. By aggregating a plurality of estimates of the solution, the accuracy of the final estimate of the solution accounts (at least to some extent) for the multiplicity of equivalent solutions caused by noise. It should be appreciated that the aggregation of a plurality of independent estimates for the minimum of χ²(a) in method 18 may be of greater benefit in instances in which the estimates are linearly parameterized, see equation (4), as non-linear parameterization of the minimization of χ²(a) may reduce the impact of noise on the solution, see equation 18. However, this is not intended to be limiting, and method 18 may be used in conjunction with a non-linear parameterization of the solution without departing from the scope of this disclosure.

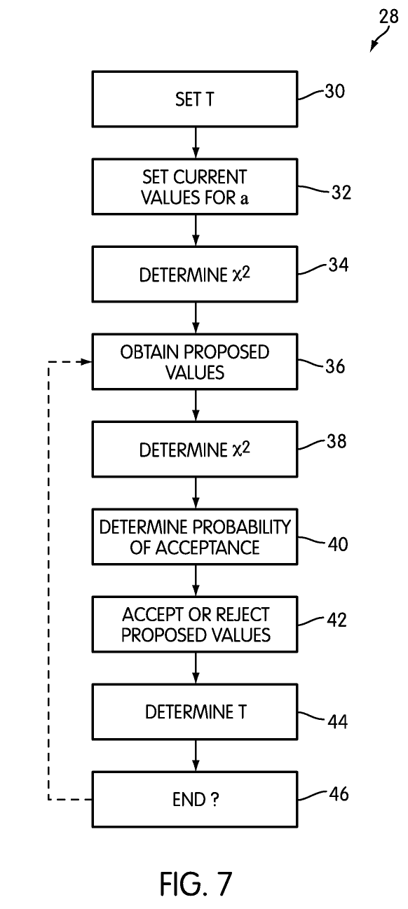

FIG. 7 illustrates a method 28 of inverting NMR data via a global optimization algorithm to determine a proton density (e.g., at operation 16 of method 10, at operation 20 of method 18, etc.), according to one embodiment of the invention. In particular, method 28 includes implementing a simulated annealing algorithm. It should be appreciated that the illustration of a simulated annealing algorithm in method 28 should not be viewed as limiting. As has been set forth above, it is contemplated that a variety of global optimization algorithms may be implemented in determining a proton density from NMR data.

Generally, the simulated annealing algorithm is based on an analogy with physical systems: a set of variables that make up the components of an m-space vector a are the degrees of freedom of a fictitious physical system, which form the configuration space. The function E(a)=/χ²(a) is considered to be the system's energy and the problem is reduced to that of finding the minimum energy or ground state configuration of the system. It is known that if the fictitious physical system is heated to a very high temperature T and then it is slowly cooled down to the absolute zero temperature (a process known as annealing), the system will find itself in the ground state (i.e., the configuration in the configuration space with the minimum amount of retained energy). The cooling rate must be slow enough in order to avoid getting trapped in some metastable state (i.e., local minima of E(a)). At temperature T, the probability of being in a configuration with energy E(a) is given by the Boltzmann-Gibbs factor:

exp(−E(a)/T). (14)

The Boltzmann-Gibbs factor demonstrates that high energy configurations can appear with a finite probability at high T. If the temperature is lowered, those high energy states become less probable and, as T→0 only the states near the minimum of E(a) have a non-vanishing probability to appear. Thus, within the fictitious physical system formed by the configuration space for χ²(a), as the configuration of a is manipulated in a random (or pseudo-random manner) and the temperature is appropriately decreased so that T→0 the decreasing temperature restrains the permitted configurations of a such that the configuration of a slowly converges to the configuration for a at the lowest energy state (where χ²(a) is minimized) in the configuration space.

In one embodiment, method 28 includes an operation 30, at which an initial value of a current temperature T is set. The initial value of the current temperature T is set high enough so that method 28 is enabled to explore a relatively large amount of the configuration space of the χ²(a) function.

At an operation 32, a current set of values for the parameters (i.e., components) of a are obtained. For example, if a is made up of m parameters, then m values for the parameters are obtained at operation 32. In one embodiment, the m values are determined in a random manner. As used within this disclosure, the term “random” encompasses both purely random and pseudo-random determinations.

At an operation 34, the value of the χ²(a) function for the current set of values for the parameters of a are determined. Within the lexicography of simulated annealing, this value is the “energy” for the configuration described by the current set of m values for the parameters of a, E(a).

At an operation 36, a proposed set of values for the m parameters of a is obtained. In one embodiment, operation 36 includes implementing the Monte Carlo method to determine the proposed set of values. This is not intended to be limiting, as other algorithms, such as the hybrid Monte Carlo method, Hamiltonian dynamics, and/or other algorithms may be implemented in determining the proposed set of values at operation 36. More particularly, in one embodiment, the proposed set of values is determined by altering the current set of values for the m parameters of a according to a proposed change. Since, the values of the parameters of a are always positive, an adequate stochastic dynamic may be implemented to obtain the proposed set of values. For example, a log-normal random walk similar to the following may be implemented:

log(a′)=log(a)+σG; (15)

where a′ is an m-space vector having the proposed set of values for the parameters of a, G is an m-spaced vector (similar to a) with all components equal to zero except one, which is a random number distributed according to a normal distribution N(0, 1) (Gaussian distribution with center at zero and standard deviation one). The factor σ scales the standard deviation to σ. It should be appreciated that although this implementation effectively only varies a single value from the current set of values to the proposed set of values, other implementations may be used to determine the proposed set of values from the current set of values in which more than one value is varied.

At an operation 38, the value of χ² for the proposed set of values for the parameters of a (i.e., χ²(a′)) is determined. Within the lexicography of simulated annealing, the value determined at operation 38 is the energy of the configuration described by the proposed set of values for the parameters of a, and can be expressed as E(a′).

At an operation 40, a probability of accepting the proposed set of values for the m parameters of a as the current set of values for the m parameters of a is determined. This proposed set of values is accepted with a probability P_{acc}(a′|a). In one embodiment, the probability P_{acc} (a′|a) is determined according to the Metropolis acceptance as follows:

$${P}_{acc} ( {a}^{′} \vert a ) = min \{ 1 , {e}^{- \frac{E ( {a}^{′} ) - E ( a )}{T}} \} ; \qquad ( 16 )$$

where T again represents the current temperature. In other embodiments, acceptance algorithms other than the Metropolis acceptance may be implemented to determine the probability of accepting the proposed set of values at operation 40.

At an operation 42, the proposed set of values for the m parameters of a are accepted or rejected according to the probability determined at operation 40. If the proposed set of values are accepted, then the proposed set of values becomes the current set of values for the m parameters of a. If the proposed set of values are rejected, then the current set of values for the m parameters of a remain unchanged.

At an operation 44, a new value for the current temperature is determined. The new value for the current temperature may be determined according to an annealing schedule that describes the current temperature as a function of the number of iterations of operations 36-42 that have been performed. An example of such an annealing schedule can be expressed as follows:

T(k)=T(0)e^{-λk}; (17)

where k is the number of iterations of operations 36-42 that have been performed. It should be appreciated that in some instances, the current temperature may not be updated at operation 44 for every iteration. For example, to conserve processing resources and/or enhance the speed of the algorithm, the illustration of operation 44 in FIG. 7 also represents instances in which the current temperature is only updated every few iterations.

At an operation 46, a determination is made as to whether the algorithm should perform another iteration. In one embodiment, this determination is based on whether the current temperature will allow for a significant reduction in energy. If it is determined that another iteration should be made, then method 28 returns to operation 36. If it is determined that another iteration should not be made, then the current set of values for the m parameters of a are determined to be representative of the proton density distribution.

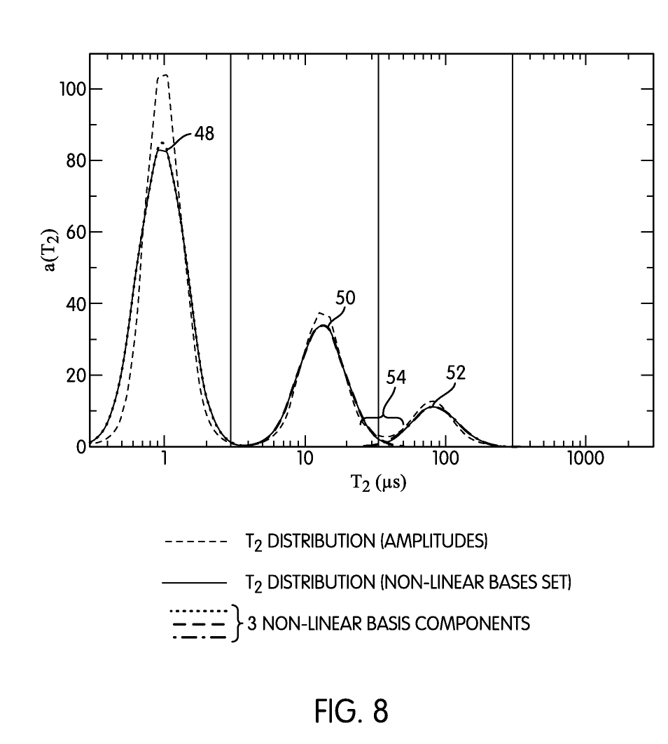

FIG. 8 illustrates another proton density distribution. In the description of method 28 above, the m parameters determined were linear (i.e., the amplitude a(T₂) as a function of T₂). However, this is not intended to be limiting. One of the enhancements enabled by the implementation of a global optimization algorithm to determine the proton density distribution is that the solution may be parameterized according to a non-linear basis function. Implementing a non-linear basis function to parameterize the solution of a global optimization algorithm (e.g., the simulated annealing technique illustrated in FIG. 7) may reduce the number of parameters required to describe the solution. This, in turn, means that parameterizing the solution with a non-linear basis function will reduce the computation required to arrive at the solution. The reduction in the number of parameters becomes even more pronounced in multi-dimension solutions, as the number of parameters that must be determined (and/or or the reduction in number of parameters that have to be determined that is enabled by non-linear parameterization) is multiplied exponentially as each additional dimension is added. Other enhancements may also accompany non-linear parameterization, some of which are discussed further below. Hereafter, the non-linear parameterization of the solution according to a Gaussian basis function will be discussed as an example of a non-linear parameterization. This is not intended to be limiting as a variety of other non-linear basis function could also be implemented. For example, the non-linear parameterization may be accomplished according to a Gamma basis function, a B-spline basis function, or an experimentally determined basis function.

As can be seen in FIG. 8, the proton density distribution generally resembles a spectrum with a set of consecutive peaked distributions. These peaked distributions generally correspond to different types of fluid bound in the porous media from which the NMR data is obtained. For example, a first peak 48 in the single dimension distribution shown in FIG. 8 is generally associated with clay-bound fluid, a second peak 50 is generally associated with capillary-bound fluid, and a third peak 52 is generally associated with “free” fluid. Because of the general shape of peaks 48, 50, and 52, each of peaks 48, 50, and 52 may be described by a single Gaussian distribution whose parameters are center, width, and amplitude.

In one embodiment, parameterizing the solution according to a non-linear basis function comprises essentially the same set of operations as were described above with respect to the solution of the linear parameters by executing method 28. Referring back to FIG. 7, at operation 32, a set of values for the parameters of a parameter vector are obtained (e.g., according to a random or pseudo-random determination). Parameterization of the solution according to a set of N_{G} Gaussian basis function components enables the T₂ optimization problem to be expressed as (compare with equation (4) above):

$${χ}^{2} ( x ) ≡ E ( x ) = {\sum }_{i = 1}^{n} {[ {b}_{i} - {\sum }_{j = 1}^{m} {K}_{ij} {\sum }_{k = 1}^{{N}_{g}} {e}^{{a}_{k} - {( \frac{log ( {T}_{j} ) - {b}_{k}}{{c}_{k}} )}^{2}} ]}^{2} ; \qquad ( 18 )$$

where aₖ represents the amplitude of a basis component, bₖ the center, and cₖ the width, and k represents the different series of basis components from 1 to N_{G}. From this representation, it can be seen that the parameters to optimize can be combined in a single m-space vector (where m=3*N_{G}) expressed as x={a₁, b₁, c₁, . . . , a_{N}_{_{g}}, b_{N}_{_{g}}, c_{N}_{_{g}}}. From equation (18), χ²(x) is solved for the current set of values for the m parameters of x at operation 34.

At operation 36, a proposed set of values for the m parameters of x are determined. Since each component of x (“x₁”) represents only one of several possible parameter types, this operation may be more involved than the description of operation 36 above for the linear parameters. In particular, because each component of x may be of a specific parameter type (e.g., a, b, c), a permissible range may be established for each parameter type to keep the optimization within the physically possible limits of the system. For instance, this may include specification of a minimum, a maximum and a range for each parameter type (e.g., a^{del}=a^{max}−a^{min}, b^{del}=b^{max}−b^{min}, c^{del}=c^{max}−c^{min}). From these specified constraints, a set of m-space constraint vectors x^{min}, x^{max}, and x_{del} may be determined.

In one embodiment, operation 36 again includes the implementation of the Monte Carlo method in the form of a constrained Lorentzian random walk to determine the proposed set of values (represented below as x′). This random walk can be expressed as:

x′=x+σL; (19)

where σ is a scaling factor that may vary as a function of the number of iterations of operations 36-42 that have been accomplished, and L is an m-space vector, where all components equal zero except one, L₁, which is a random number distributed according to a Lorentzian distribution.

It must be checked that the new proposed value lies on the allowed range for that parameter, otherwise a new proposal is generated. Tails in Lorentzian distributions are larger than in Gaussians, so an effective long-range sampling is achieved, which may promote a greater performance of the simulated annealing method 28, such as the improvement generally known as “fast simulated annealing.”

At operation 38, χ²(x′) is determined from the proposed set of values obtained at operation 36. At operation 40, the probability of accepting the proposed set of values is determined. For example, the Metropolis acceptance probability described above with respect to a and a′ may be implemented (e.g.,

$${P}_{acc} ( {x}^{′} \vert x ) = min \{ 1 , {e}^{- \frac{E ( {x}^{′} ) - E ( x )}{T}} \} ) .$$

At operation 42, the proposed set of values are accepted or rejected according to the probability determined at operation 40. Operations 44 and 46 proceed substantially as was discussed above.

Returning to FIG. 8, typically, first peak 48 associated with clay-bound fluid is located within a predetermined zone of the spectrum formed by the proton density distribution (e.g., T₂ε[0.3,3]). Similarly, second peak 50 is generally located within a predetermined zone (e.g., T₂ε[3,33]), and third peak 52 is generally located within a predetermined zone (e.g., T₂ε[33,300]). Further, a fourth peak (not shown in FIG. 8) is sometimes present and is associated with a second type of free fluid. The fourth peak is also generally located within a predetermined zone in the spectrum shown in FIG. 8 (e.g., T₂ε[300,3000] in μs). It should be appreciated that other zone partitions are possible, and that these values are provided merely for illustrative purposes.

In one embodiment, the optimization method discussed above, wherein the solution is parameterized according to a non-linear set of parameters, the solution is parameterized such that a single basis component is fit (during the optimization) to the proton density distribution within each of the predetermined zones. This further enhances the optimization in that the impact by each “type” of fluid within the porous media is associated with a single basis component, which enables the contribution to the proton density distribution of a given fluid type to be tracked even where it crosses into a zone of the spectrum typically associated with another fluid type. For example, this is illustrated at region 54 in FIG. 8. As can be seen, the individual basis components associated with second peak 50 and third peak 52 overlap. In a more conventional solution (e.g., a solution implementing linear parameters), the boundary illustrated in FIG. 8 between the zones that contain second peak 50 and third peak 52 would be used to divide the contributions to the proton density distribution of the fluid types associated with second peak 50 and third peak 52. However, the discretization of these contributions enabled by fitting a single non-linear basis component to each of second peak 50 and third peak 52 enables the contribution of fluid types that form second peak 50 and third peak 52 to be tracked across the boundary.

Although the invention has been described in detail for the purpose of illustration based on what is currently considered to be the most practical and preferred embodiments, it is to be understood that such detail is solely for that purpose and that the invention is not limited to the disclosed embodiments, but, on the contrary, is intended to cover modifications and equivalent arrangements that are within the spirit and scope of the appended claims. For example, it is to be understood that the present invention contemplates that, to the extent possible, one or more features of any embodiment can be combined with one or more features of any other embodiment.

What is claimed is:

1. A computer-implemented method of obtaining a proton density distribution, the method comprising:
acquiring nuclear magnetic resonance data from porous media;
inverting the nuclear magnetic resonance data via a global optimization algorithm to determine a proton density distribution within the porous media; and
outputting the determined proton density distribution.

2. The method of claim 1, wherein the proton density distribution is parameterized according to a nonlinear basis function.

3. The method of claim 2, wherein the nonlinear basis function comprises one or more of a Gaussian basis function, a Gamma basis function, a B-spline basis function, or an experimentally determined basis function.

4. The method of claim 2, wherein the proton density distribution comprises one or more spectra comprised of a plurality of predetermined zones, one or more of the predetermined zones having a peak of the distribution therein, and wherein inverting the nuclear magnetic resonance data via a global optimization algorithm to determine the proton density distribution comprises fitting a single basis component to the distribution in each of the predetermined zones that has a peak of the distribution therein.

5. The method of claim 4, wherein individual ones of the predetermined zones are determined to correspond to different fluid types within the porous media such that a given predetermined zone corresponds to a corresponding fluid type within the porous media.

6. The method of claim 1, wherein the global optimization algorithm comprises one or more of simulated annealing, genetic algorithm, evolutionary strategies, or parallel tempering.

7. The method of claim 6, wherein the sampling technique implemented by the simulated annealing algorithm comprises one or more of a Monte Carlo method, a hybrid Monte Carlo method, Hamiltonian dynamics, or a random walk method.

8. The method of claim 1, wherein the proton density distribution is an n-dimensional distribution, and n is greater than 2.

9. The method of claim 1, wherein inverting the nuclear magnetic resonance data via a global optimization algorithm to determine a proton density distribution comprises:
implementing the global optimization algorithm two or more times to determine a plurality of solutions for the proton density distribution; and
averaging the plurality of solutions for the proton density distribution.

10. The method of claim 9, wherein the proton density distribution is lineal representation of amplitudes.

11. A computer-implemented method of obtaining a proton density distribution, the method comprising:
acquiring nuclear magnetic resonance data from porous media;
determining a proton density distribution of the porous media from the nuclear magnetic resonance data, wherein the proton density distribution comprises one or more spectra comprised of a plurality of predetermined zones, one or more of the predetermined zones having a peak of the distribution therein, and wherein determining the proton density distribution comprises parameterizing the proton density distribution according to a non-linear basis function by fitting a single basis component to the distribution in each of the predetermined zones that has a peak of the distribution therein; and
outputting the determined proton density distribution.

12. The method of claim 11, wherein the nonlinear basis function comprises one or more of a Gaussian basis function, a Gamma basis function, a B-spline basis function, or an experimentally determined basis function.

13. The method of claim 11, wherein individual ones of the predetermined zones are determined to correspond to different fluid types within the porous media such that a given predetermined zone corresponds to a corresponding fluid type within the porous media.

14. The method of claim 13, wherein the predetermined zones comprise one or more of a predetermined zone that corresponds to clay bound fluid, a predetermined zone that corresponds to capillary bound fluid, or a zone that corresponds to one or more types of free fluid.

15. The method of claim 11, wherein determining a proton density distribution of the media from the nuclear magnetic resonance data comprises implementing a global optimization algorithm.

16. The method of claim 15, wherein the global optimization algorithm comprises one or more of simulated annealing, genetic algorithm, evolutionary strategies, or parallel tempering.

17. The method of claim 16, wherein the sampling technique implemented by the simulated annealing algorithm comprises one or more of a Monte Carlo method, a hybrid Monte Carlo method, Hamiltonian dynamics, or a random walk method.

18. The method of claim 11, wherein the proton density distribution is an n-dimensional distribution, and n is greater than 2.

19. A method of obtaining information related to a proton density distribution, the method comprising:
acquiring nuclear magnetic resonance data from media;
defining a function that implements the acquired nuclear magnetic resonance data and depends on m parameters of the proton density distribution such that the function is minimized as a solution for the m parameters of the proton density distribution is approached;
implementing a global optimization algorithm to determine the solution for the m parameters of the proton density distribution; and
outputting the solution for the m parameters of the proton density distribution.

20. The method of claim 19, wherein implementing the global optimization algorithm to determine a solution for the m parameters of the proton density distribution comprises:
(a) setting an initial value of a current temperature for the algorithm;
(b) determining a current set of values for the m parameters randomly;
(c) determining a value of the function for the current set of values for the m parameters;
(d) determining a proposed set of values for the m parameters by randomly adjusting one or more of the values in the current set of values for the m parameters;
(e) determining a value of the function for the proposed set of values for the m parameters;
(f) calculating a probability of accepting the proposed set of values for the m parameters as the current set of values for the m parameters based on the value of the function for the current set of values for the m parameters, the value of the function for the proposed set of parameters, and the current temperature;
(g) accepting or rejecting the proposed set of values for the m parameters as the current set of values for the m parameters based on the probability calculated at (f); and
(h) determining a new value for the current temperature for the algorithm such that the current temperature decreases as a function of the iterations of the algorithm.

21. The method of claim 20, wherein each of (a)-(h) are performed in the order set forth, and the method further comprises, subsequent to (h), returning to (d).

22. The method of claim 19, wherein the m parameters are non-linear.

23. The method of claim 19, wherein implementing a global optimization algorithm to determine the solution for the m parameters comprises:
implementing the global optimization algorithm two or more times to determine a plurality of solutions for the m parameters; and
averaging the plurality of solutions for the m parameter.

24. The method of claim 23, wherein the m parameters are linear.

25. The method of claim 19, wherein the proton density distribution is an n-dimensional distribution, and n is greater than 2.
